(19) United States
(12) Patent Application Publication
(10) Pub. No.: US 2011/0279980 A1
(43) Pub. Date: Nov. 17, 2011

(54) HEAT DISSIPATION STRUCTURE FOR LIQUID CRYSTAL TELEVISION

(75) Inventors: Tsai-Chih Tsai, Xindian City (TW); Jhih-Jhong Jian, Pingtung (TW); Yin-Chieh Hsueh, Kaohsiung City (TW)

(73) Assignee: Silicon Integrated Systems Corp., Hsinchu City (TW)

(21) Appl. No.: 12/778,048

(22) Filed: May 11, 2010

(51) Int. Cl. H05K 7/20

(52) U.S. Cl. 361/710

(57) ABSTRACT

A heat dissipation structure for a liquid crystal television is disclosed. The liquid crystal television includes a front plate and a rear plate. The front plate has a screen and a metal backboard. The heat dissipation structure includes a printed circuit board (PCB) mounted to the metal backboard; a television integrated circuit (IC) chip for controlling operations of the liquid crystal television being attached on the PCB; and one or more heat dissipating posts provided between the PCB and the metal backboard. The heat generated by the television IC chip is dispersed to the metal backboard via the heat dissipating post or posts.

### TECHNICAL FIELD OF THE INVENTION

The present invention relates to heat dissipation, more particularly, to a heat dissipation structure for a liquid crystal television.

### BACKGROUND OF THE INVENTION

In a low price liquid crystal television, printed circuit broads (PCBs) are implemented with PCBs having only two copper sheets to reduce the cost. However, such PCBs have poor heat dispersing performance. In order to maintain a television IC (integrated circuit) chip operating normally, a heat sink is usually used to disperse the heat from the television IC chip.

FIG. 1 is a schematic diagram showing a sectional view of a general liquid crystal television 1 with a conventional heat sink 40. As shown, the liquid crystal television 1 includes a front plate 10 having a television screen 12 mounted on a front side thereof and a metal backboard 14 mounted on a rear side thereof. The liquid crystal television 1 further includes a rear plate 18, which is assembled with the front plate 10 to constitute the liquid crystal television 1.

A main printed circuit board (PCB) 20 is mounted on a rear side of the metal backboard 14 by means of pillars 25. A television IC chip 30, which controls operations of the liquid crystal television 1, is installed on the main PCB 20. FIG. 2 is a schematic diagram showing an EP-LQFP (Exposed Pad Low-profile Quad Flat Package) type of television IC chip 30 mounted on the PCB 20. As shown in the drawing, the PCB 20 has metal portions 202, 204, 206, 208. The television IC chip 30 has a die 32 disposed on a metal pad 38 and leads 34 electrically connected with the die 32 by wires (not shown). The die 32 is packed by package material 36. The bottom of the metal pad 38 is exposed from the package material 36 and is mounted on the metal portion 204 of the PCB 20 by means of solder 29. As shown, the metal portion 204 at the top side of the PCB 20 is connected with the metal portion 208 at the bottom side of the PCB 20 by VIAs 210. These VIAs 210 are through holes penetrating the PCB 20 and having metal (e.g. copper) plated on inner surfaces thereof.

The PCB 20 has only two copper sheets for the sake of low cost. Accordingly, heat dispersion for the television IC chip 30 is poor. As the television IC chip 30 operates functions, a temperature thereof will be increased. Once the television IC chip 30 is overheated, it may operate abnormally.

To avoid such a problem, a heat sink 40 is attached to the television IC chip 30 to assist the television IC chip 30 to dissipate the heat, as shown in FIG. 3. However, the heat sink 40 with multiple fins is thick and occupies a considerable space, and thereby hindering the liquid crystal television 1 from being further thinned. In addition, the heat sink 40 is expensive.

It will be highly satisfactory if a low cost solution to the above problems is provided.

### SUMMARY OF THE INVENTION

An objective of the present invention is to provide a heat dissipation structure for a liquid crystal television. The liquid crystal television includes a front plate and a rear plate. The front plate has a screen installed at a front side and a metal backboard mounted at a back side thereof. The front plate and the rear plate are assembled to form the liquid crystal television. By using the heat dissipation structure, the heat generated by the television IC chip can be effectively dispersed with a low cost.

In accordance with the present invention, the heat dissipation structure comprises a printed circuit board (PCB) mounted to the metal backboard; a television integrated circuit (IC) chip for controlling operations of the liquid crystal television being attached on the PCB; and one or more heat dissipating posts provided between the PCB and the metal backboard. At least one of the heat dissipating posts is located at a position corresponding to the television IC chip. Preferably, the heat dissipating post is located at a position aligning with a die embedded within the television IC chip.

### BRIEF DESCRIPTION OF THE DRAWINGS

The present invention will be described in detail in conjunction with the appending drawings, in which:

FIG. 1 is a schematic diagram showing a sectional view of a general liquid crystal television with a conventional heat sink;

FIG. 2 is a schematic diagram showing an EP-LQFP chip mounted on a PCB;

FIG. 3 is a schematic diagram showing an EP-LQFP chip with a conventional heat sink, which is mounted on a PCB;

FIG. 4 is a schematic diagram showing a heat dissipation structure in accordance with an embodiment of the present invention;

FIG. 5 is a schematic diagram showing a section view of a liquid crystal television provided with the heat dissipation structure of FIG. 4;

FIG. 6 is a schematic diagram showing a section view of a liquid crystal television provided with a heat dissipation structure in accordance with another embodiment of the present invention; and

FIG. 7 is a schematic diagram showing a section view of a liquid crystal television provided with a heat dissipation structure in accordance with a further embodiment of the present invention.

### DETAILED DESCRIPTION OF THE INVENTION

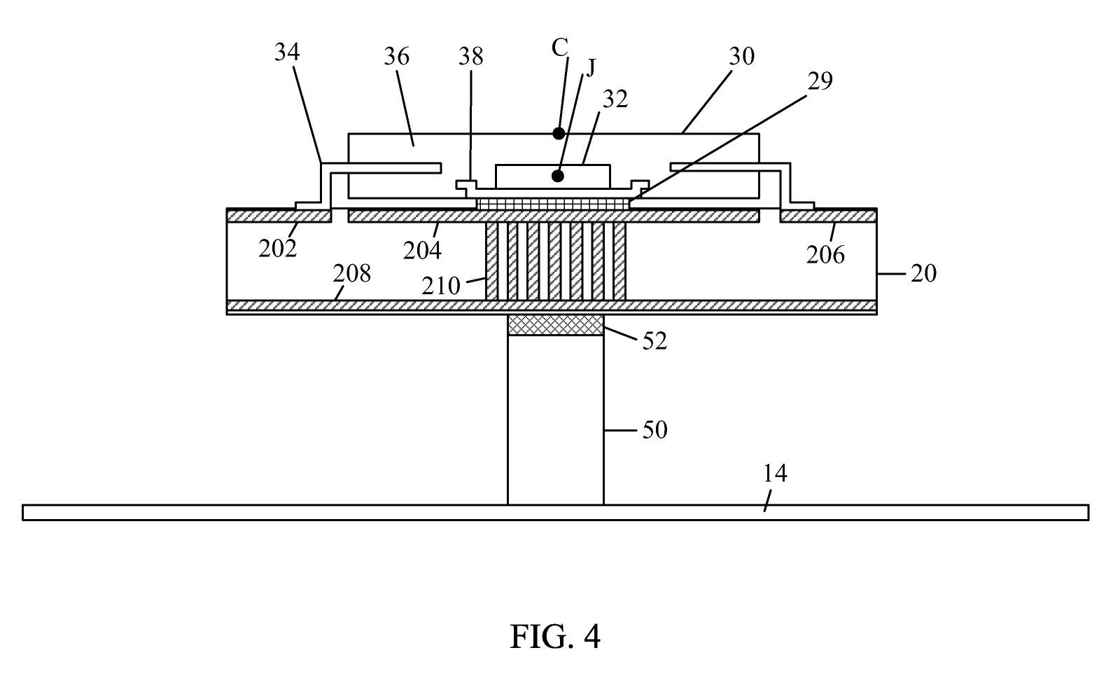

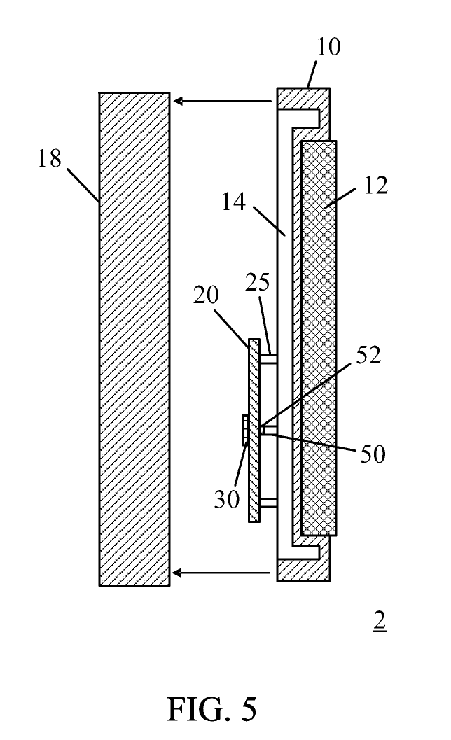

FIG. 4 is a schematic diagram showing a heat dissipation structure in accordance with an embodiment of the present invention. FIG. 5 is a schematic diagram showing a section view of a liquid crystal television 2 provided with the heat dissipation structure of FIG. 4. The same reference numbers of these drawing and other drawings indicate the same components, and the relevant descriptions will be omitted to avoid repetition and redundancy.

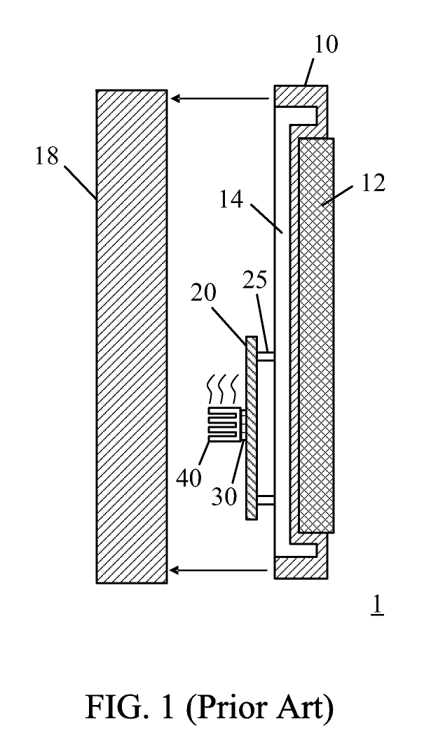

Similar to FIGS. 1-3, an EP-LQFP type of television IC chip 20 is disposed on a PCB 20. The PCB 20 is mounted on a metal backboard 14 of a front plate 10 of the liquid crystal television 2 by means of pillars 25. In the present invention, no convention heat sink is used. As shown, a heat dissipating post 50 is provided between the PCB 20 and the metal backboard 14. The dissipating post 50 is made of heat conductive material such as metal (e.g. aluminum). The position where the dissipating post 50 is located is corresponding to the television IC chip 30. Preferably, the dissipating post 50 is positioned to align with a die 32 embedded in the television IC chip 30 so as to effectively transfer the heat from the die 32 to the metal backboard 14. As known, the die 32 is usually embedded in the center of the television IC chip 30. By doing so, heat dispersion is achieved. As known, the metal backboard 14 has a great area, and therefore the effect of heat dispersion is good.

The cost of the heat dissipating post 50 is quite low as compared to a heat sink. In addition, setting up the heat dissipating post 50 is easy. The heat dissipating post 50 can be provided along with the pillars 25, which are used to mount the PCB 20 to the metal backboard 14 as mentioned above.

To avoid formation of a gap between the dissipating post 50 and the PCB 20, thermal conductive paste 52 is applied on an end of the heat dissipating post 50, which is connected with a metal portion 208 on the bottom side of the PCB 20. The thinner the thermal conductive paste 52 is, the better the heat dispersion performance can be achieved, but the higher the temperature of the metal backboard 14 will be. In practice, the thickness of the thermal conductive paste 52 is about 1 mm, for example.

As can be seen in FIG. 5, in the absence of the heat sink (e.g. the heat sink 40 in FIG. 1), a front plate 10 and a rear plate 18 of the liquid crystal television 2 can be closer to each other, and therefore the whole thickness of the liquid crystal television 2 can be reduced.

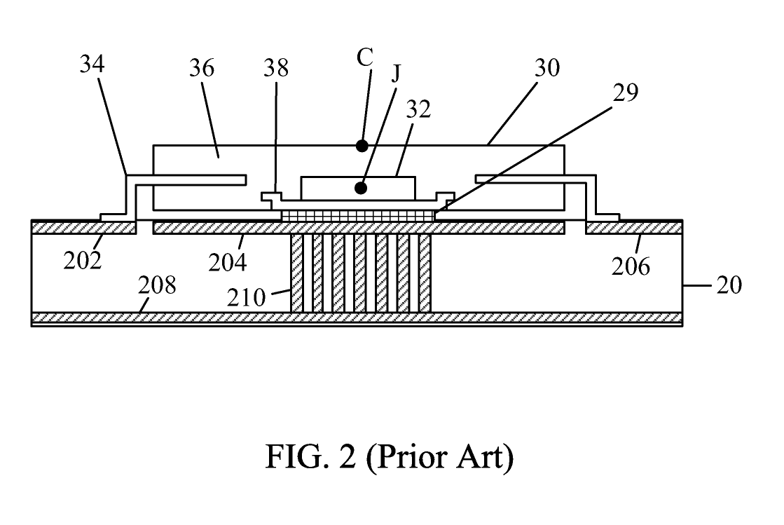

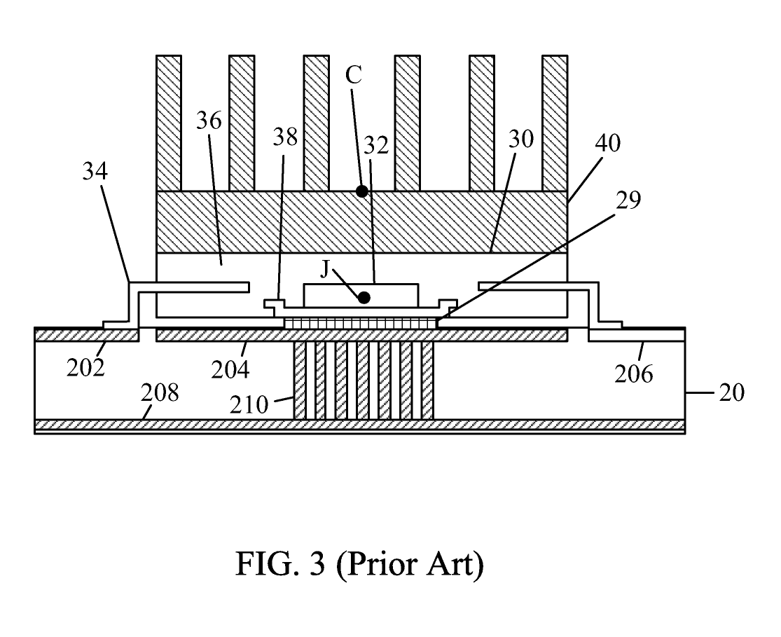

To manifest the effect of the present invention, the inventor carried out an experiment by software, in which the temperatures of the television IC chip 30 in the conditions shown in FIGS. 2, 3 and 4 were measured. The ambient temperature was 25° C. The television IC chip 30 operated at its full power of 3.6 watts. For each condition of FIG. 2, FIG. 3 and FIG. 4, the temperature T_{c} at a point C was measured, and the temperature T_{J} at a point J was estimated, as shown in Table 1.

TABLE 1
Temperatures of the chip and die

| | | | With heat |
|---|---|---|---|
| | No heat dispersion | With heat sink | dissipating post |
| | means (FIG. 2) | (FIG. 3) | (FIG. 4) |
| T_{C} (° C.) | 85.9 | 55.2 | 67.2 |
| Ψ_{JC} (° C./Watt) | 0.08 | 3.69 | 0.08 |
| T_{J} (° C.) | 86.2 | 68.5 | 67.5 |

Where Ψ_{JC} is the thermal resistivity between the point C and the point J. In FIG. 2 or FIG. 4, the temperature T_{C} at the point C is the temperature measured from the top surface of the television IC chip 30. It is noted that the temperature at the top surface of the television IC chip 30 in FIG. 3 is not possible to be measured. Accordingly, in FIG. 3, the point C is at a base of the heat sink 40, and the temperature T_{C} is the temperature of the base of the heat sink 40. This temperature should be close to the actual temperature at the surface of the television IC chip 30.

As can be seen from the table, for the chip surface, the heat dissipation efficiency of the present invention, in which the heat dissipating post 50 is used, is about 61% as compared to the situation where the heat sink 40 is used. However, for the heat dissipation of the die 32, the present invention is superior to the prior art. In this case, the temperature of the metal backboard 14 is increased by 6.2° C. Such a temperature rise will not noticeably influence the screen 12, and therefore is acceptable.

The heat dissipation structure of the present invention is particularly effective for an exposed pad type of IC chip such as EP-LQFP or EP-TQFP ((Exposed Pad thin-profile Quad Flat Package) type of IC chip. However, such a structure can also be used to other types of IC chips. For example, a PBGA (plastic ball grid array) type of IC chip can also be applied with the present invention.

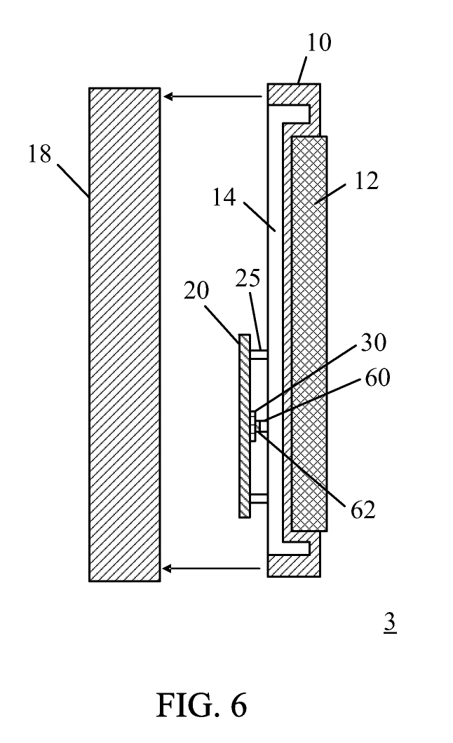

FIG. 6 is a schematic diagram showing a section view of a liquid crystal television 3 provided with a heat dissipation structure in accordance with another embodiment of the present invention. In the present embodiment, a television IC chip 30 is mounted on a PCB 20 as the previous embodiment. However, the PCB 20 is reversely mounted to a metal backboard 14 of the liquid crystal television 3, so that the television IC chip 30 is positioned on a surface of the PCB 20 facing the metal backboard 14. A heat dissipating post 60 is provided between the television IC chip 30 and the metal backboard 14. Thermal conductive paste 62 is applied to an end of the heat dissipating post 60 toward the television IC chip 30 to prevent any gap from being formed therebetween.

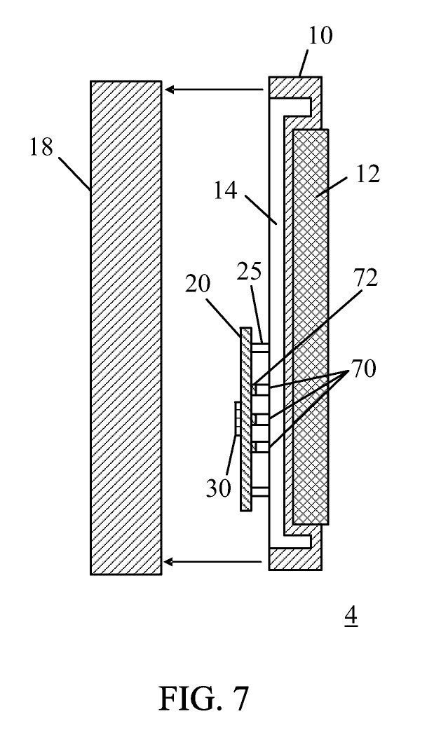

FIG. 7 is a schematic diagram showing a section view of a liquid crystal television 4 provided with a heat dissipation structure in accordance with a further embodiment of the present invention. As compared to the embodiment shown in FIG. 5, in the present embodiment, several heat dissipating posts 70 are provided. One of the heat dissipating posts 70 (e.g. the middle one in this drawing) is disposed to correspond to the center of a television IC chip 30. In general, a die (not shown in this drawing) is embedded in the center of the television IC chip 30. Accordingly, the middle heat dissipating post 70 substantially aligns with the die. The other heat dissipating posts 70 are disposed in the vicinity of the middle one. Thermal conductive paste 72 is applied to an end of each heat dissipating post 70 connected with the television IC chip 30 to prevent any gap from being formed therebetween.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A heat dissipation structure for a liquid crystal television, the liquid crystal television including a front plate having a screen and a metal backboard and a rear plate, the structure comprising:
a printed circuit board (PCB) mounted to the metal backboard;
a television integrated circuit (IC) chip for controlling operations of the liquid crystal television, the television IC chip being attached on the PCB; and
at least one heat dissipating post provided between the PCB and the metal backboard.

2. The heat dissipating structure of claim 1, wherein the heat dissipating post is located at a position corresponding to the television IC chip.

3. The heat dissipating structure of claim 2, wherein the heat dissipating post is located at a position substantially aligning with a die within the television IC chip.

4. The heat dissipating structure of claim 1, wherein multiple heat dissipating posts are provided, and one of the heat dissipating posts is located to substantially align with a die within the television IC chip.

5. The heat dissipating structure of claim 1, wherein the heat dissipating post is provided on a side of the PCB facing the metal backboard and the television IC chip is attached on the other side of the PCB.

6. The heat dissipating structure of claim 1, wherein the television IC chip is attached on a side of the PCB facing the metal backboard and the heat dissipating post is provided between the television IC chip and the metal backboard.

7. The heat dissipating structure of claim 1, wherein the heat dissipating post is made of heat conductive material.

8. The heat dissipating structure of claim 7, wherein the heat dissipating post is made of metal.

9. The heat dissipating structure of claim 8, wherein the heat dissipating post is made of aluminum.

10. The heat dissipating structure of claim 1, further comprising thermal conductive paste applied at an end of the heat dissipating post toward the PCB.

11. The heat dissipating structure of claim 1, wherein the television IC chip is an exposed pad (EP) type of chip.

12. The heat dissipating structure of claim 11, wherein the television IC chip is an EP-LQFP (Exposed Pad Low-profile Quad Flat Package) type of chip.
